(19) United States
(12) Patent Application Publication
(10) Pub. No.: US 2012/0018849 A1
(43) Pub. Date: Jan. 26, 2012

(54) SEMICONDUCTOR DEVICE AND METHOD OF MANUFACTURING THE SAME

(75) Inventors: Kazuyuki SUTO, Ashikaga-shi (JP); Hiroaki Tomita, Ota-shi (JP)

(73) Assignee: ON Semiconductor Trading, Ltd., Hamilton (BM)

(21) Appl. No.: 13/186,227

(22) Filed: Jul. 19, 2011

(30) Foreign Application Priority Data
Jul. 20, 2010 (JP) 2010-162436

(51) Int. Cl. H01L 29/06; H01L 21/78

(52) U.S. Cl. 257/618; 438/113; 257/E29.022; 257/E21.599

(57) ABSTRACT

In a CSP type semiconductor device, the invention prevents a second wiring from forming a protruding portion toward a dicing line at the time of forming the second wiring that is connected to the back surface of a first wiring formed near a side surface portion of a semiconductor die on the front surface and extends onto the back surface of the semiconductor die over a step portion in a window that is formed from the back surface side of the semiconductor die so as to expose the back surface of the first wiring. A glass substrate is bonded on a semiconductor substrate on which a first wiring is formed on the front surface near a dicing line with a resin as an adhesive being interposed therebetween. The semiconductor substrate is then etched from the back surface to form a window having inclined sidewalls with the dicing line as a center. A second wiring is then formed so as to be connected to the back surface of the first wiring exposed in the window and extend over one of the sidewalls of the window, that extends perpendicular to the dicing line, onto the back surface of the semiconductor substrate.

### CROSS-REFERENCE OF THE INVENTION

This application claims priority from Japanese Patent Application No. JP2010-162436, the content of which is incorporated herein by reference in its entirety.

### BACKGROUND OF THE INVENTION

1. Field of the Invention:

The invention relates to a semiconductor device and a method of manufacturing the same, in particular, to a semiconductor device and a method of manufacturing the same relating to forming a wiring extending over a step portion near a dicing line from the lower surface to the upper surface of the step portion.

2. Description of the Related Art:

In a process of manufacturing a semiconductor device, a pattern need be formed over various step portions such as a LOCOS (Local Oxidation of Silicon) step, a polysilicon wiring step, an aluminum wiring step and so on from the lower surfaces to the upper surfaces of these step portions by a photolithography process. In this case, since exposure light incident perpendicularly on a step portion is reflected obliquely, sometimes a pattern transferred on a semiconductor substrate does not correspond to a photomask pattern.

In a manufacturing line in which miniaturization is enhanced, a photoresist is mainly of a positive type. In a case of a positive resist, a reticle (photomask) of which a portion for forming a pattern on a semiconductor substrate is black is used, and the positive resist on the semiconductor substrate that is exposed to light perpendicularly entering through the transparent portion of the reticle is removed through a development process. The black pattern of the reticle is transferred on the semiconductor substrate.

In this case, light reflected at various step portions as described above existing on the semiconductor substrate may enter under the black pattern of the reticle and the photoresist in a portion that should not be exposed to light may be exposed to the light. The resist in the portion where light enters under the pattern to be transferred on the semiconductor substrate is also removed through a development process, resulting in foaming a smaller pattern on the semiconductor substrate than a designed pattern or resulting in separation of the pattern in a worse case.

In a case of forming a large pattern by a design rule that does not need miniaturization of a semiconductor substrate, ordinarily, a positive type photoresist is not used and a negative type photoresist is used. In this case, a negative resist irradiated with light is hardened and a negative resist in a portion that is not irradiated with light is removed through a development process.

Therefore, even if a negative resist under a black pattern of a reticle is exposed to light reflected at a step portion, the width of the hardened negative resist only increases to form a protruding portion in the pattern, and separation does not occur in the pattern. Ordinarily, the increased width of the pattern does not cause a problem in a case of a non-miniaturized design rule.

As a method of preventing an abnormal pattern such as a narrowing or protruding portion from being transferred on a semiconductor substrate by light reflected at a step portion, covering a surface of an object to be exposed with a reflection preventing film, treating a photoresist material, and so on are disclosed in Japanese Patent Application Publication Nos. Hei 9-69479, Hei 9-211849 and 2005-072554.

In a case of forming an electrode pattern having high reflectance over a step portion formed on a semiconductor substrate from the lower surface to the upper surface, the probability that an abnormal pattern such as a narrowing portion is formed on the semiconductor substrate by light reflected at the step portion increases more. Such an abnormal pattern causes a problem usually when a miniaturized positive type photoresist is used. Japanese Patent Application Publication Nos. Hei 9-69479 and so on belong to this case.

Ordinarily, in a case of using a negative resist for a large pattern by a design rule, exposure light reflected at a step portion does not cause a serious problem since it only slightly enlarges a transferred pattern on a semiconductor substrate. However, there is a case that light reflected at a step portion causes a problem even in a case of using a negative resist for a large pattern by a design rule.

This is in a case where a glass substrate 4 or the like is bonded on a semiconductor substrate 1 on which a first wiring 3 is formed on the front surface side near a dicing line S and the semiconductor substrate 1 is etched from the back surface side of the semiconductor substrate 1 to expose the back surface of the first wiring 3 as shown in FIG. 6A. In this case, a step portion D is formed, having a thickness of about 100 μm or more and having an inclined surface from the back surface of the semiconductor substrate 1 to the back surface of the first wiring 3 formed on the front surface of the semiconductor substrate.

When a second wiring 8 connected to the back surface of the first wiring 3 and extending over this step portion D onto the back surface of the semiconductor substrate 1 is formed by using a negative type photoresist, light reflected at the step portion D may provide the second wiring 8 with an abnormal pattern as a protruding portion 8b toward the dicing line S on the outside of the portion connected to the first wiring 3 as shown in FIG. 3.

When the second wiring 8 has the protruding portion 8b protruding toward the dicing line S, a blade in a dicing process contacts the protruding portion 8b. The wiring material contacting the blade is spread on the sidewall of the adhesive layer 5 that bonds the semiconductor substrate 1 and the glass plate 4 and so on.

In this case, the wiring material spread on the adhesive layer 5 and so on may be connected to the second wiring 8, and the wiring material is exposed from the sidewall on the dicing line. Furthermore, when the wiring material of an adjacent second wiring 8 is spread on the adhesive layer 5 and so on in the same manner, the spread wiring materials contact, thereby causing a problem that the adjacent second wirings 8 are connected through the wiring materials.

Therefore, when the second wiring 8 is formed over the step portion D existing near the dicing line S, it is necessary to prevent the second wiring 8 from having the abnormal protruding portion 8b protruding toward the dicing line S.

### SUMMARY OF THE INVENTION

The invention provides a semiconductor device that includes a semiconductor die having a front surface, a back surface and a side surface connecting the front and back surfaces, and a concave portion formed in the back surface of the semiconductor die so that in plan view of the semiconductor die a first edge of the concave portion is defined by the side surface of the semiconductor die and a second edge of the concave portion is defined by an inclined sidewall that is not parallel to the first edge. The inclined sidewall is inclined so that the concave portion is wider at the back surface than at the front surface. The device also includes a first insulation film disposed on the front surface of the semiconductor die, a second insulation film disposed on the back surface of the semiconductor die, a first wiring disposed on the first insulation film, and a second wiring disposed on the second insulation film and connected to the first wiring that is exposed in the concave portion through the first insulation film. The second wiring extends from the back surface to the front surface of the semiconductor die over the inclined sidewall. The device further includes a supporting substrate bonded to the front surface of the semiconductor die, and an adhesive layer bonding the supporting substrate to the front surface of the semiconductor die.

The invention also provides a method of manufacturing a semiconductor device. The method includes providing a semiconductor substrate having a first insulation film disposed on a first surface of the semiconductor substrate and a pair of first wirings disposed on the first insulation film. A dicing line of the semiconductor substrate runs between the pair of the first wirings. The method also includes bonding a supporting substrate to the first surface of the semiconductor substrate using an adhesive, forming an opening in the semiconductor substrate so as to expose the first insulation film by removing part of the semiconductor substrate from a second surface of the semiconductor substrate opposite from the first surface so that in plan view of the semiconductor substrate the opening comprises edges. Each of the edges is defined by an inclined sidewall, and the inclined sidewalls are inclined so that the opening is wider at the second surface than at the first surface. The method further includes forming a second insulation film on the second surface of the semiconductor substrate, exposing the first wirings by removing part of the first insulation film in the opening, forming a second wiring on the second insulation film so as to be connected to the exposed first wirings in the opening and so as to extend over one of the inclined sidewalls that is not parallel to the dicing line, forming a notch in the semiconductor substrate from the second surface along the dicing line, and dividing the semiconductor by dicing along the notch.

### BRIEF DESCRIPTION OF THE DRAWINGS

FIG. 1 is an enlarged plan view of a semiconductor device on the back surface, showing a semiconductor device and a method of manufacturing the same of an embodiment of the invention.

FIG. 2 is an enlarged plan view of a semiconductor device on the back surface, showing a semiconductor device and a method of manufacturing the same of a modification of the embodiment of the invention.

FIG. 3 is an enlarged plan view of a semiconductor device on the back surface, showing a semiconductor device and a method of manufacturing the same of a comparison example.

FIG. 4 is a cross-sectional view showing the semiconductor device of the embodiment of the invention.

FIG. 5 is a cross-sectional view showing the method of manufacturing the semiconductor device of the embodiment of the invention.

FIGS. 6A and 6B are cross-sectional views showing the method of manufacturing the semiconductor device of the embodiment of the invention.

FIGS. 7A and 7B are cross-sectional views showing the method of manufacturing the semiconductor device of the embodiment of the invention.

FIGS. 8A and 8B are cross-sectional views showing the method of manufacturing the semiconductor device of the embodiment of the invention.

FIGS. 9A and 9B are cross-sectional views showing the method of manufacturing the semiconductor device of the embodiment of the invention.

FIGS. 10A and 10B are cross-sectional views showing the method of manufacturing the semiconductor device of the embodiment of the invention.

FIGS. 11A and 11B are cross-sectional views showing the method of manufacturing the semiconductor device of the embodiment of the invention.

FIGS. 12A and 12B are cross-sectional views showing the method of manufacturing the semiconductor device of the embodiment of the invention.

FIGS. 13A and 13B are cross-sectional views showing the method of manufacturing the semiconductor device of the embodiment of the invention.

FIG. 14 is a plan view of a semiconductor device on the back surface, showing the semiconductor device and the method of manufacturing the same of the embodiment of the invention.

FIGS. 15A, 15B and 15C are views showing a state of reflection of incident exposure light at a step portion of a semiconductor substrate covered by a metal layer.

### DETAILED DESCRIPTION OF THE INVENTION

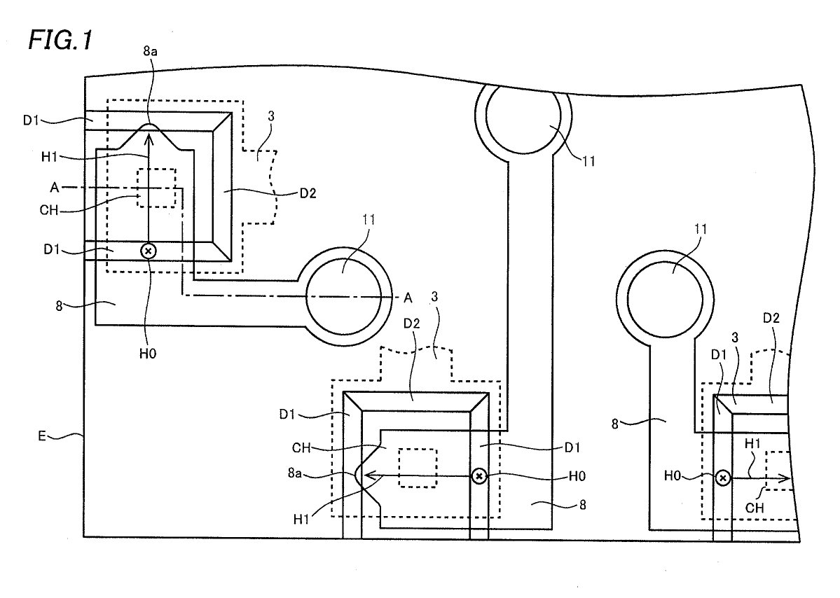

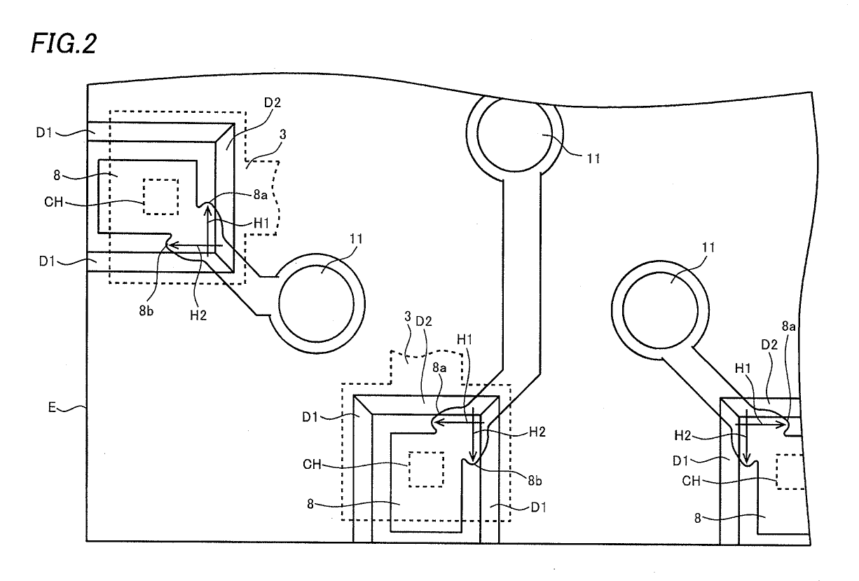

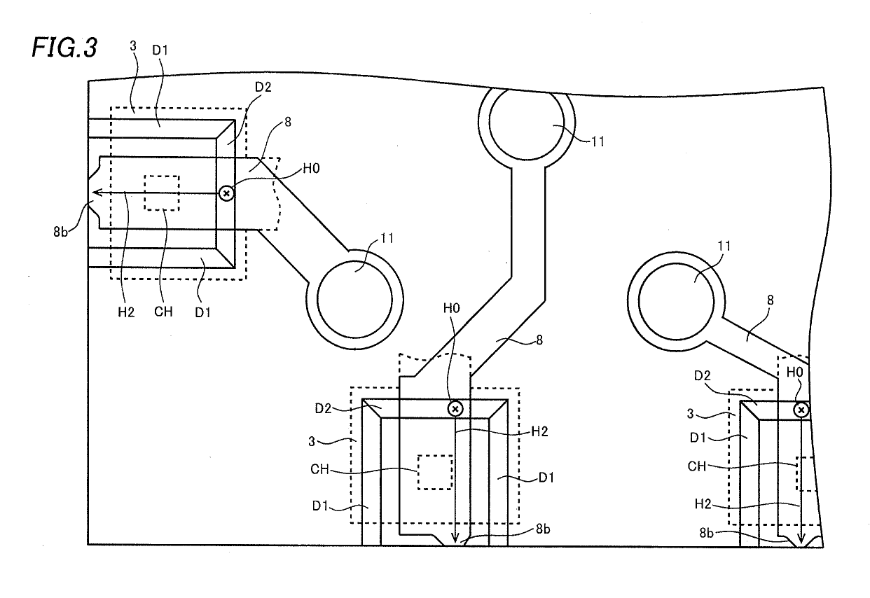

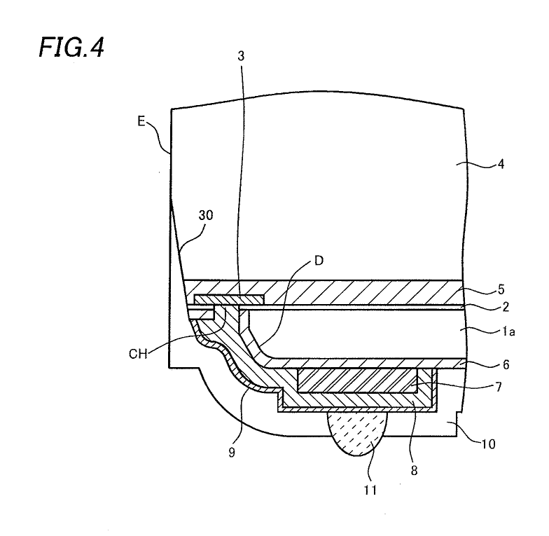

A semiconductor device of the invention will be described referring to FIGS. 1, 2, 4 hereafter. FIGS. 1 and 2 show a part of an enlarged schematic plan view of a semiconductor device from the back surface side. FIG. 4 is a schematic cross-sectional view along A-A of FIG. 1. The semiconductor device of the invention is a CSP (Chip Size Package) type semiconductor device. FIG. 3 shows a schematic plan view of a semiconductor device having a problem from the back surface side for comparison, differing from the invention.

As shown schematically in FIG. 4, the semiconductor device of the invention has a semiconductor die 1a on which a first wiring 3 is formed on the front surface near the end portion, and a glass substrate 4 is bonded on the front surface of the semiconductor die 1a with an adhesive layer 5 being interposed therebetween. Furthermore, the end surface of the semiconductor die 1a has a step portion D extending from the back surface side of the semiconductor die 1a to the back surface of the first wiring 3 and having an inclined surface. A second wiring 8 extends over the step portion D, being connected to the first wiring 3 and extending from the end portion of the semiconductor die 1a to the back surface of the semiconductor die 1a with a second insulation film 6 being interposed therebetween.

As shown by a plan view of FIG. 1, the step portion D includes two step portions D1 extending perpendicular to an end surface E of the semiconductor device 50 and a step portion D2 extending parallel with the end surface E. It means that the step portion D forms a concave portion from the end surface of the semiconductor die 1a toward the inner portion.

In the semiconductor device of the invention, as shown in FIG. 1, the second wiring 8 extending from the end portion of the semiconductor die 1a onto the back surface of the semiconductor die 1a extends over the step portion D1 of the step portion D that extends perpendicular to the end surface E of the semiconductor device 50.

As a result of this, as shown by a manufacturing method described below, exposure light H0 incident on the step portion D1 from the back surface side of the semiconductor die 1a is reflected at the step portion D1 to turn into reflection light H1 shown by an arrow, and a portion of a negative resist for forming a pattern that should not be exposed to light is exposed to the light to form a protruding portion 8a on the end of the second wiring 8. However, the protruding portion 8a of the second wiring 8 is not formed on the end surface E side of the semiconductor device 50, and formed toward another step portion D1.

Furthermore, in the semiconductor device of the invention, as shown in FIG. 2, the second wiring 8 extends obliquely over sidewall surfaces where the step portion D1 extending perpendicular to the end surface E of the semiconductor device 50 and the step portion D2 extending parallel with the end surface E of the semiconductor device 50 abut, onto the back surface. In this case, a small protruding portion 8b is formed toward the end surface E of the semiconductor device 50 by reflected light H2 from the step portion D2, and a small protruding portion 8a is formed toward the opposite another step portion D1 by reflected light H1 from the step portion D1.

The protruding portion 8a and so on are small since the second wiring 8 is formed so as to obliquely extend onto the back surface over the sidewall surfaces where the step portion D1 and the step portion D2 abut and the areas of both of the step portion D1 and the step portion D2 that are exposed to light are smaller and the amount of reflected light is also smaller than in the case of FIG. 1 as shown in the figure.

FIG. 3 shows a state in a case where the second wiring 8 is formed over the step portion D2 extending parallel with the end surface E of the semiconductor device 50 as a comparison example. Exposure light H0 incident on the step portion D2 turns into reflected light H2 shown by an arrow and travels toward the end surface E of the semiconductor device 50 on the outside of the second wiring 8. As a result, the negative resist in that portion is exposed to the light, resulting in forming a protruding portion 8b on the end portion of the second wiring 8 toward the end surface E of the semiconductor device 50.

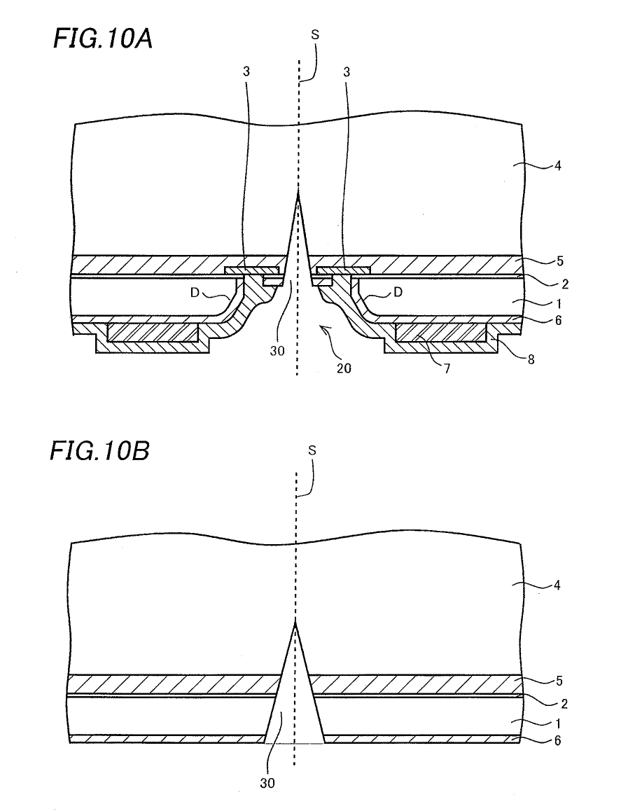

When a notch 30 is formed by dicing as shown in FIG. 10A, the protruding portion 8b connected to the second wiring 8 contacts a dicing blade and is spread on the exposed surface of the adhesive layer 5 and so on exposed at the notch 30 portion by the blade. This spread second wiring material is exposed from a protection layer 10 in a portion of a supporting substrate 4 at which the end portion of the notch 30 and the end surface E of the semiconductor device abut. Moisture or the like enters from this exposed portion and the spread second wiring material is corroded or the like. In the case where the spread portion is connected to the second wiring 8, the second wiring 8 is also corroded or the like. See FIG. 3.

On the other hand, the semiconductor device of the invention prevents the second wiring 8 from forming the protruding portion 8b on its end portion on the end portion of the semiconductor die 1a by forming the second wiring 8 over the step portion D1 or over the sidewall portion where the step portion D1 and the step portion D2 abut. As a result of this, the second wiring 8 is not exposed on the outside of the protection layer 10 or the like, thereby realizing a high reliability semiconductor device.

The second wiring 8 extending over the step portion D1 perpendicular to the end surface E of the semiconductor device 50 onto the back surface side of the semiconductor die 1a in this manner is a feature of the invention.

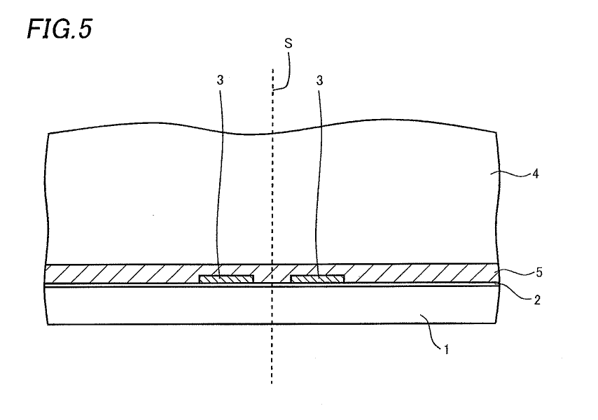

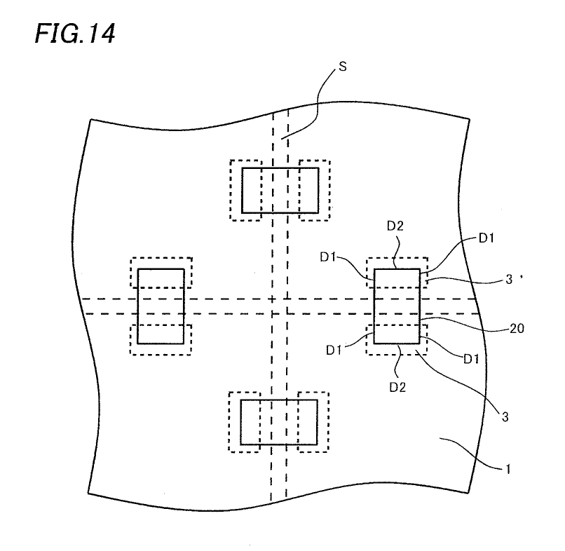

Hereafter, a method of manufacturing the semiconductor device of the invention will be described referring to cross-sectional views of the semiconductor device in FIGS. 5 to 13B and a plan view of the semiconductor device on the back surface side in FIG. 14.

First, as shown in FIG. 5, a semiconductor substrate 1 is prepared. Semiconductor elements such as, for example, a CCD image sensor, a semiconductor memory or the like are formed on the semiconductor substrate 1 by a semiconductor process. The first wirings 3 are formed on the front surface with a first insulation film 2 being interposed therebetween, being disposed at a predetermined interval near a dicing line S for dividing the semiconductor dies in a subsequent process. At this time, the first wiring 3 is a pad extended from a bonding pad of the semiconductor device to near the dicing line S. In detail, the first wiring 3 is an external connection pad and electrically connected to a circuit (not shown) of the semiconductor device.

Then, the glass substrate 4 for use as a supporting substrate is bonded on the semiconductor substrate 1 on which the first wirings 3 are formed, using a resin 5 (e.g. epoxy resin) as a transparent adhesive. Although a glass substrate is used as the supporting substrate and an epoxy resin is used as the adhesive in the embodiment, a silicon substrate or a plastic substrate may be used as the supporting substrate and an adhesive suitable for this supporting substrate may be used as the adhesive.

Then, the surface of the semiconductor substrate 1 opposite to the surface on which the glass substrate 4 is bonded is back-ground to decrease the thickness of the substrate. Scratches occur on the back-ground surface of the semiconductor substrate 1, forming concaves and convexes with width and depth of about several μm. In order to minimize these concaves and convexes, the concaves and convexes of the semiconductor substrate 1 are wet-etched using an etchant of which the etching rate for the silicon substrate as the semiconductor substrate 1 is higher than that for the silicon oxide film 2 as the first insulation film 2.

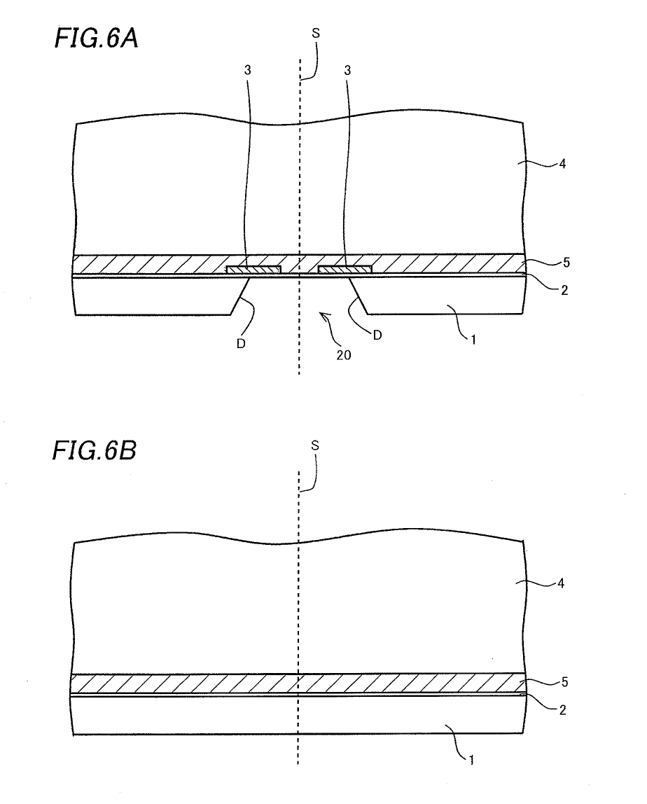

Then, as shown in FIGS. 6A and 6B, isotropic etching is performed to the semiconductor substrate 1 from the surface opposite to the surface on which the glass substrate 4 is bonded, using a resist pattern (not shown) as a mask provided with an opening so as to expose the first wirings 3 partially. As a result, as shown in FIG. 6A, a window 20 is formed around the dicing line S in a portion where the first wirings 3 exist, and the first insulation film 2 is exposed. On the other hand, in a portion where the first wirings 3 do not exist, as shown in FIG. 6B, the semiconductor substrate 1 remains as it is. As a result, a plan view of the semiconductor device in FIGS. 6A and 6B on the semiconductor substrate 1 side is as shown in FIG. 14.

The window 20 has the step portion D with inclined sidewalls as shown in FIG. 6A. Furthermore, as shown in FIG. 14, the step portion D includes the step portions D1 extending perpendicular to the dicing line S and the step portions D2 extending parallel with the dicing line S. The directions of reflected light H1 and so on of exposure light H0 incident on the step portion in a photolithography process differ depending on the inclination angle of the step portion D. When the second wiring 8 is formed in a subsequent photolithography process, the protruding portion 8a and so on may occur on the end portion of the second wiring 8, depending on the inclination angle of the step portion D.

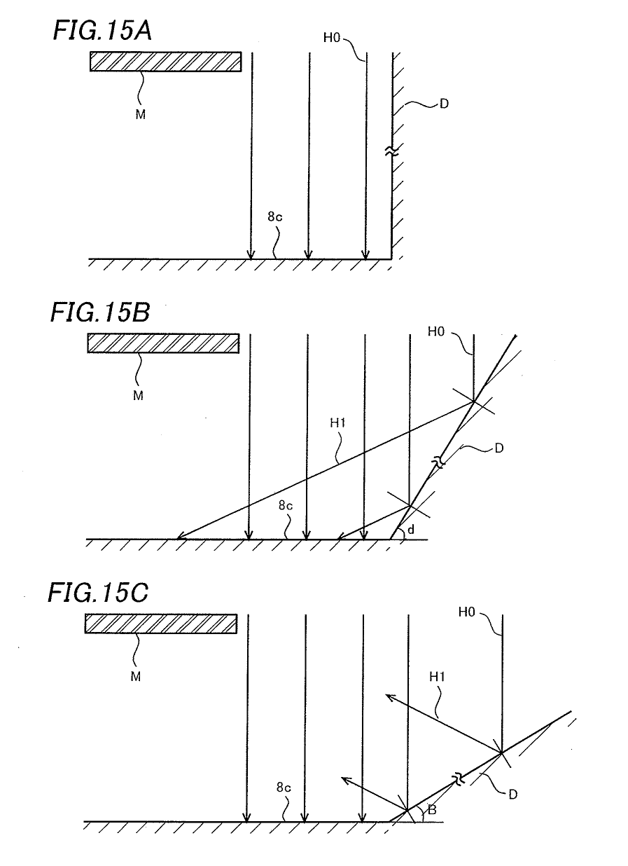

FIGS. 15A, 15B and 15C show the direction of reflected light H1 from the step portion D when exposed to light H0 in a photolithography process. FIG. 15A is in a case where the inclination angle of the step portion D is perpendicular to the bottom surface of the semiconductor substrate 1. In this case, the incident light H0 at the time of exposure in the photolithography process is parallel with the step portion D, and thus there does not exist reflected light H1 from the step portion D when exposed to the light H0. Therefore, the exposure light transfers a reticle pattern M as it is on a negative resist applied on a second wiring material 8c.

On the other hand, in a case where the inclination angle α of the step portion D is larger than 45° and smaller than 90° as shown in FIG. 15B, the reflected light H1 from the step portion D enters under the reticle pattern M. The reflected light H1 from a more upper level of the step portion D enters under the reticle pattern M more deeply. The negative resist even under the reticle pattern M is exposed to this reflected light H1, and a pattern larger than the reticle pattern is transferred on the negative resist on the second wiring material 8c.

Furthermore, in a case where the inclination angle β of the step portion D is smaller than 45° as shown in FIG. 15C, the reflected light H1 reflected at the step portion D travels upward, and thus the negative resist under the reticle pattern M is not exposed to the light.

Therefore, when the second wiring 8 that will be described below is formed, in order to prevent the second wiring 8 from having the protruding portion 8a and so on by the reflected light H1 from the step portion D, the step portion D need have a vertical inclination angle or an inclination angle smaller than 45° so as to avoid the exposure of the negative resist under the reticle pattern M.

However, the vertical inclination angle of the step portion D degrades the step coverage of the second wiring 8 that is only several μm while the height of the step portion D is about 100 pm or more, and thus there occurs a problem such as the disconnection of the second wiring 8. When the inclination angle of the step portion D is smaller than 45°, there occurs a problem that the occupation area of the step portion D is too large.

Therefore, the inclination angle of the step portion D need be larger than 45° and smaller than 90°, at which the reflected light H1 enters under the reticle pattern M. Therefore, it is necessary to avoid forming the protruding portion 8a toward the dicing line S even if the reflected light H1 enters thereunder in the process of forming the second wiring that will be described below.

In the same manner as FIG. 6A and FIG. 6B, the following description about the subsequent processes uses A for a cross-sectional view of a portion where the window 20 is formed, and uses B for a cross-sectional view in a portion where the window 20 is not formed.

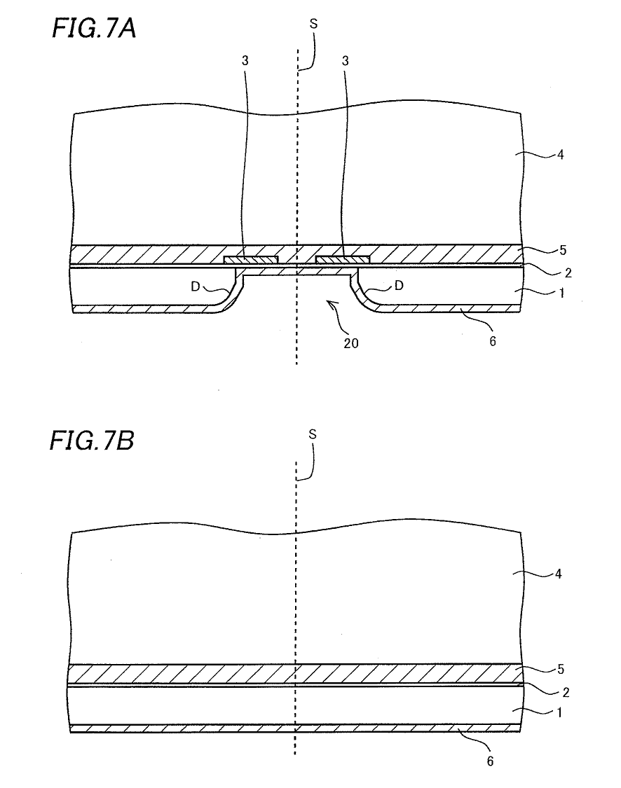

Then, as shown in FIGS. 7A and 7B, a second insulation film 6 is deposited on the surface of the semiconductor substrate 1 that is opposite to the surface where the glass substrate 4 is bonded. In the embodiment, a silane-based oxide film of about 3 μm is deposited.

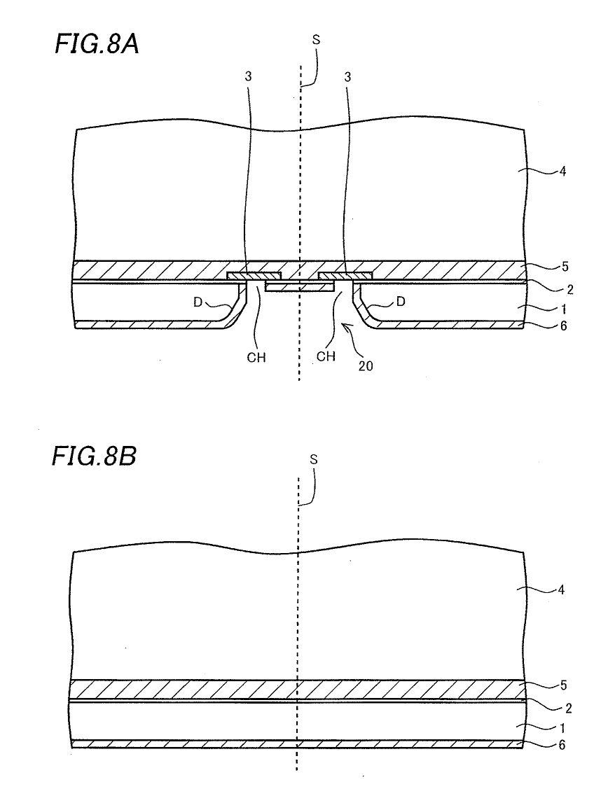

A resist (not shown) is then formed on the surface of the semiconductor substrate 1 that is opposite to the surface on which the glass substrate 4 is bonded and patterning is performed thereto so as to form contact holes CH for partially exposing the first wirings in the window 20, thereby forming a resist film. Then, as shown in FIGS. 8A and 8B, the second insulation film 6 and the first insulation film 2 are etched using the resist film (not shown) as a mask to form the contact holes CH and partially expose the first wirings 3.

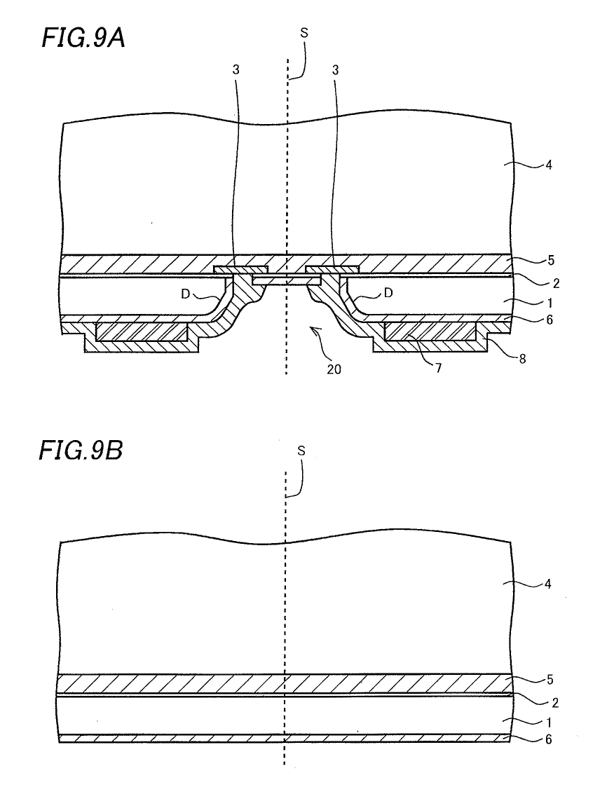

Then, as shown in FIGS. 9A and 9B, buffer members 7 having elasticity are formed in positions corresponding to conductive terminals 11 to be formed in a subsequent process. The buffer members 7 have a function of absorbing stress applied to the conductive terminals 11 and relieve stress applied when the conductive terminals 11 are bonded, although the buffer members 7 are not necessarily used in the invention.

The second wirings 8 are then formed on the surface opposite to the glass substrate 4. The structure of the second wiring is a feature of the invention, and thus will be described in detail hereafter. First, the wiring material film such as aluminum is deposited on the back surface of the semiconductor substrate 1 including in the window 20 by a predetermined sputtering method or the like.

A negative resist is then applied on the wiring material by a predetermined method. The negative resist applied on the wiring material is then exposed to light through a reticle pattern that is transparent in a portion where the second wiring 8 is to be formed and black in the other portion. The exposed negative resist is hardened, and the negative resist in the non-exposed portion is dissolved and removed by the subsequent development process.

As a result, the pattern of the second wiring 8 by the negative resist is formed on the wiring material . The wiring material is then etched by predetermined wet-etching or dry-etching to form the second wiring 8. By this, the first wiring 3 and the second wiring 8 are electrically connected.

The second wiring is connected to the first wiring 3 and extends over the step portion D onto the back surface of the semiconductor substrate 1 with the second insulation film 6 being interposed therebetween. In this case, the step portion D over which the second wiring 8 extends is the step portion D1 shown in FIGS. 1 and 14. Exposure light H0 incident in the step portion D1 turns into reflected light H1 toward another step portion D1 that is on the opposite side over the bottom surface of the step portion D as shown in FIG. 1. As a result, the protruding portion 8a is formed toward another step portion D1 that is on the opposite side. Even when this protruding portion 8a exists, the protruding portion 8a does not cause a problem since it does not contact a blade for dicing the semiconductor substrate 1 and so on that will be described below.

A resist (not shown) is then applied on the surface opposite to the glass substrate 4. At this time, in the portion where the window 20 is formed, the resist film is patterned so as to form an opening in a portion along the dicing line S in the window 20. On the other hand, in the portion where the window 20 is not formed, the resist film is patterned so as to expose the second wiring 8. Etching is then performed using this resist film (not shown) as a mask to remove the second wiring 8 around the dicing line S. Furthermore, the second wiring 8 in the portion where the window 20 is not formed is removed.

As shown in FIGS. 10A and 10B, the notch 30 (a reversed V shaped groove) is formed along the dicing line S by cutting the glass substrate 4 so as to have a depth of, for example, about 30 μm. At this time, it is necessary to use a blade having a width such that the blade does not contact the second wiring 8 in the window 20.

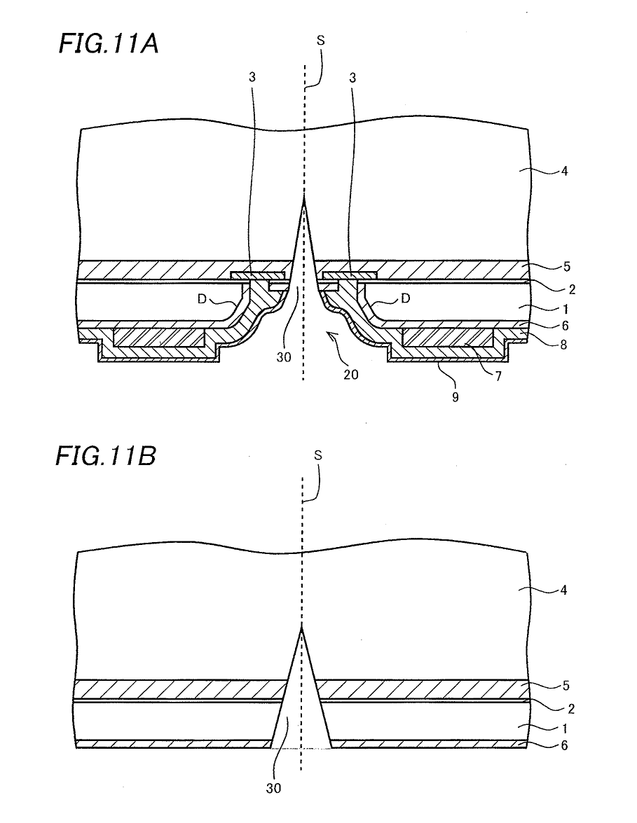

Supposing the second wiring 8 extends over the step portion D2 shown in FIG. 14 onto the back surface of the semiconductor substrate 1, the protruding portion 8b as shown in FIG. 3 is formed toward the dicing line S in FIG. 14. In this case, the blade contacts the protruding portion 8b, causing a problem that the second wiring material connected to the second wiring 8 is spread on the sidewall of the notch 30. A Ni—Au plating film 9 shown in FIG. 11 that will be described below is formed on the surface of the wiring material spread on the sidewall of the notch 30.

The second wiring material is also spread on the sidewall of the notch 30 by the blade that contacts the protruding portion 8b of the adjacent second wiring 8 and the Ni—Au plating film 9 is also formed on that surface. In this case, the wiring materials that are spread on the sidewalls of the notch 30 from the protruding portions 8b of these adjacent second wirings 8 may contact each other.

When these wiring materials spread on the sidewalls of the notch 30 contact each other, this results in a short circuit between the adjacent second wirings 8 through the wiring materials spread on the notch 30, causing a problem in the yield and reliability of the semiconductor device.

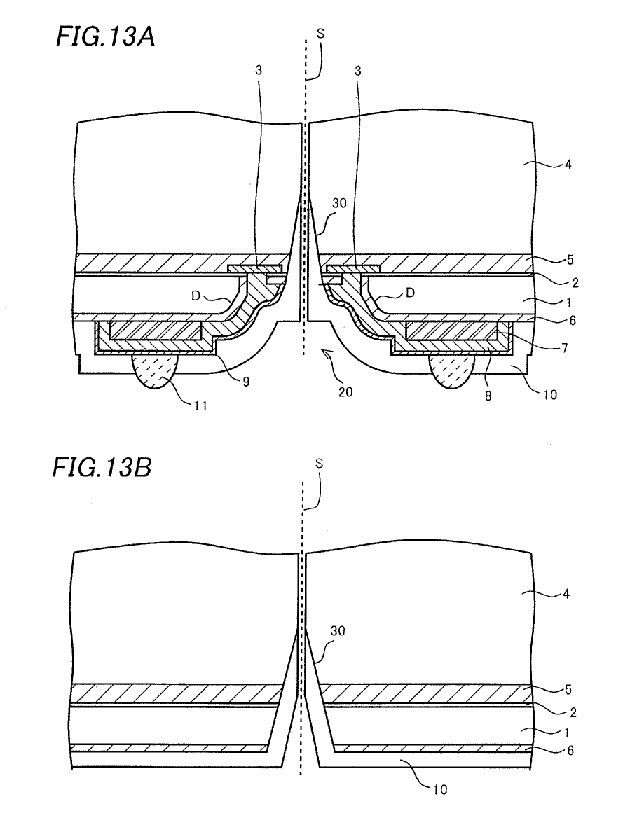

Furthermore, the wiring material spread on the sidewall of the notch 30 and provided with the Ni—Au plating film 9 on the surface may reach the end of the notch 30. In this case, as shown in FIG. 13A, when the semiconductor substrate 1 and so on are divided into individual semiconductor devices by dicing, the wiring material and so on spread on the sidewall of the notch 30 are exposed from the protection film 10 at the end portion of the notch 30.

The wiring material spread on the sidewall of the notch 30 and so on that are exposed from the protection film 10 are corroded or the like due to outside moisture or the like. When the corrosion or the like is enhanced, even the second wiring 8 itself is corroded through the sidewall portion of the notch 30, causing a serious problem in the reliability.

Then, as shown in FIGS. 11A and 11B, an electroless plating treatment is performed to the surface opposite to the glass substrate 4 to form the Ni—Au plating film 9 on the second wiring 8. This film is formed by plating, and thus formed only in the portion where the second wiring 8 exists. As described above, when the second wiring material is spread on the sidewall of the notch 30, the Ni—Au plating film 9 is also formed thereon.

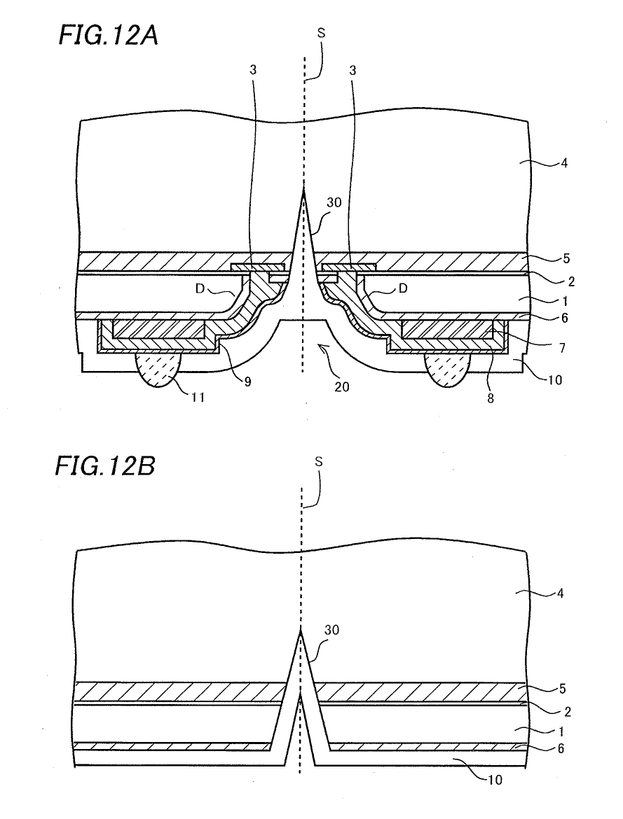

Then, as shown in FIG. 12A and 12B, the protection film 10 is formed on the surface opposite to the glass substrate 4. By this, the protection film 10 is formed on the back surface side of the semiconductor substrate 1 including on the inner sidewalls of the notch 30 formed along the dicing line S.

In detail, in the portion on the semiconductor substrate 1 where the first wirings 3 exist (i.e., in the portion along the dicing line S in the window 20), the protection film 10 is formed from the surface of the second insulation film 6 so as to cover the resin 5 and the glass substrate 4 exposed from the sidewalls of the notch 30. On the other hand, on the other region on the semiconductor substrate 1 than the portion where the first wirings 3 exist (i.e., the region where the window 20 is not formed), the protection film 10 is formed from the surface of the second insulation film 6 so as to cover the exposed portions of the second insulation film 6, the semiconductor substrate 1, the first insulation film 2, the resin 5 and the glass substrate 4 that are exposed from the sidewalls of the notch 30.

Then, the protection film 10 in portions where the conductive terminals 11 are to be formed is removed by etching using a resist mask (not shown) (having openings in positions corresponding to the buffer members 7), and the conductive terminals 11 are formed on the Ni—Au plating film 9 in the positions corresponding to the buffer members 7. This conductive terminal 11 is electrically connected to the second wiring 8 through the Ni—Au plating film 9. The conductive terminal 11 is made of a solder bump or a gold bump.

Then, as shown in FIG. 13A and 13B, dicing is performed along the dicing line S from the portion provided with the notch 30 to divide the semiconductor substrate 1 and so on into individual CSP type semiconductor devices each having the semiconductor die 1a and so on. At this time, the blade used for the dicing need have a width such that the blade cuts the glass substrate 4 and the protection film in the notch 30 only.

As described above, in the method of manufacturing the semiconductor device of the embodiment, the second wiring 8 connected to the first wiring 3 and extending onto the back surface of the semiconductor substrate 1 with the second insulation film 6 being interposed therebetween extends over the step portion D1 extending perpendicular to the dicing line S. Therefore, the protruding portion 8a on the end portion of the second wiring 8 is not faced toward the dicing line S, and the second wiring material is not spread on the sidewall of the notch 30 by the blade for the dicing.

This results in prevention of a problem that the adjacent second wirings 8 contact each other through the second wiring materials connected to the second wirings 8 spread on the sidewalls of the notch 30 or the spread second wiring material is exposed from the protection layer 10 and even the second wiring 8 and so on are corroded or the like due to moisture or the like, thereby enhancing the yield and reliability of the semiconductor device.

Since the second wiring may be formed over the two step portions D1 or over a portion where the step portion D1 and the step portion D2 abut, there is also an advantage of increasing the flexibility of the wiring layout compared with a conventional case where the second wiring is formed over the single step portion D2.

In the semiconductor device and the method of manufacturing the same of the invention, the second wiring does not abnormally protrude toward the dicing line on the lower surface of the step portion near the dicing line. Therefore, at the time of dicing the semiconductor substrate, the blade does not contact the second wiring material connected to the second wiring and spread the second wiring material on the side surface of the adhesive layer and so on, thereby producing a high reliability semiconductor device.

What is claimed is:

1. A semiconductor device comprising:
a semiconductor die comprising a front surface, a back surface and a side surface connecting the front and back surfaces;
a concave portion formed in the back surface of the semiconductor die so that in plan view of the semiconductor die a first edge of the concave portion is defined by the side surface of the semiconductor die and a second edge of the concave portion is defined by an inclined sidewall that is not parallel to the first edge, the inclined sidewall being inclined so that the concave portion is wider at the back surface than at the front surface,
a first insulation film disposed on the front surface of the semiconductor die;
a second insulation film disposed on the back surface of the semiconductor die;
a first wiring disposed on the first insulation film;
a second wiring disposed on the second insulation film and connected to the first wiring that is exposed in the concave portion through the first insulation film, the second wiring extending from the back surface to the front surface of the semiconductor die over the inclined sidewall;
a supporting substrate bonded to the front surface of the semiconductor die; and
an adhesive layer bonding the supporting substrate to the front surface of the semiconductor die.

2. The semiconductor device of claim 1, wherein the second edge of the concave portion is perpendicular to the first edge of the concave portion in the plan view.

3. The semiconductor device of claim 1, wherein the concave portion further comprises a third edge that abuts the second edge in the plan view and is defined by another inclined sidewall, and the second wiring extends over a corner of the concave portion where the second and third edges abut.

4. A method of manufacturing a semiconductor device, comprising:
providing a semiconductor substrate comprising a first insulation film disposed on a first surface of the semiconductor substrate and a pair of first wirings disposed on the first insulation film, a dicing line of the semiconductor substrate running between the pair of the first wirings;
bonding a supporting substrate to the first surface of the semiconductor substrate using an adhesive;
forming an opening in the semiconductor substrate so as to expose the first insulation film by removing part of the semiconductor substrate from a second surface of the semiconductor substrate opposite from the first surface so that in plan view of the semiconductor substrate the opening comprises edges, each of the edges being defined by an inclined sidewall, and the inclined sidewalls being inclined so that the opening is wider at the second surface than at the first surface;
forming a second insulation film on the second surface of the semiconductor substrate;
exposing the first wirings by removing part of the first insulation film in the opening;
forming a second wiring on the second insulation film so as to be connected to the exposed first wirings in the opening and so as to extend over one of the inclined sidewalls that is not parallel to the dicing line;
forming a notch in the semiconductor substrate from the second surface along the dicing line; and
dividing the semiconductor by dicing along the notch.

5. The method of claim 4, wherein the one of the inclined sidewalls over which the second wiring extends is perpendicular to the dicing line.

6. The method of claim 4, wherein another of the inclined sidewalls abuts the one of inclined sidewalls, and the second wiring is formed to extend over a corner of the opening where the two sidewalls abut.
